(19) United States
(12) Patent Application Publication
(10) Pub. No.: US 2026/0107502 A1
(43) Pub. Date: Apr. 16, 2026

(54) SEMICONDUCTOR DEVICE AND METHOD FOR MANUFACTURING

(71) Applicants: KABUSHIKI KAISHA TOSHIBA, Tokyo (JP); Toshiba Electronic Devices & Storage Corporation, Tokyo (JP)

(72) Inventors: Daichi ISHII, Kanazawa Ishikawa (JP); Hiroaki KATOU, Nonoichi Ishikawa (JP); Hiroyuki KISHIMOTO, Kanazawa Ishikawa (JP)

(73) Assignees: KABUSHIKI KAISHA TOSHIBA, Tokyo (JP); Toshiba Electronic Devices & Storage Corporation, Tokyo (JP)

(21) Appl. No.: 19/281,975

(22) Filed: Jul. 28, 2025

(30) Foreign Application Priority Data
Oct. 16, 2024 (JP) 2024-181223

(51) Int. Cl. H10D 30/66; H10D 30/01; H10D 64/00

(52) U.S. Cl. CPC H10D 30/668; H10D 30/0297; H10D 64/117

(57) ABSTRACT

A semiconductor device includes a first electrode, a second electrode, a semiconductor layer provided between the first electrode and the second electrode in a first direction, a third electrode extending in the first direction within the semiconductor layer and containing silicon, a fourth electrode extending in the first direction within the semiconductor layer, including a first side surface facing a side surface of the third electrode in a second direction orthogonal to the first direction, and a second side surface located on an opposite side of the first side surface in the second direction, an insulating film provided between the second side surface of the fourth electrode and the semiconductor layer and a nitride film in contact with a side surface of the third electrode. The nitride film is located at least in a portion facing a corner between the first side surface and the bottom surface of the fourth electrode on the side surface of the third electrode.

### CROSS-REFERENCE TO RELATED APPLICATIONS

This application is based upon and claims the benefit of priority from Japanese Patent Application No. 2024-181223, filed on Oct. 16, 2024; the entire contents of which are incorporated herein by reference.

### FIELD

Embodiments relate to a semiconductor device and a method for manufacturing a semiconductor device.

### BACKGROUND

A semiconductor device is known in which a gate electrode and a field plate electrode are provided in the same trench formed in the semiconductor layer.

### BRIEF DESCRIPTION OF THE DRAWINGS

FIG. 1 is a schematic plan view of the semiconductor device according to the first embodiment.

FIG. 2 is a schematic cross-sectional view of the semiconductor device according to the first embodiment.

FIG. 3 is a schematic cross-sectional view of the semiconductor device according to the second embodiment.

FIG. 4 is a schematic cross-sectional view of the semiconductor device according to the third embodiment.

FIG. 5 is a schematic cross-sectional view of the semiconductor device according to the fourth embodiment.

FIG. 6 is a schematic cross-sectional view of the semiconductor device according to the fifth embodiment.

FIG. 7 is a schematic cross-sectional view of the semiconductor device according to the sixth embodiment.

FIG. 8 is a schematic cross-sectional view of the semiconductor device according to the seventh embodiment.

FIG. 9 is a schematic plan view of the semiconductor device according to the eighth embodiment.

FIG. 10 is a schematic cross-sectional view of the semiconductor device according to the eighth embodiment.

FIG. 11A and FIG. 11B are schematic cross-sectional views showing the manufacturing method of the semiconductor device according to the first embodiment.

FIG. 12A and FIG. 12B are schematic cross-sectional views showing the manufacturing method of the semiconductor device according to the first embodiment.

FIG. 13A and FIG. 13B are schematic cross-sectional views showing the manufacturing method of the semiconductor device according to the first embodiment.

FIG. 14A and FIG. 14B are schematic cross-sectional views showing the manufacturing method of the semiconductor device according to the first embodiment.

FIG. 15A and FIG. 15B are schematic cross-sectional views showing the manufacturing method of the semiconductor device according to the second embodiment.

FIG. 16A and FIG. 16B are schematic cross-sectional views showing the manufacturing method of the semiconductor device according to the second embodiment.

FIG. 17A and FIG. 17B are schematic cross-sectional views showing the manufacturing method of the semiconductor device according to the second embodiment.

FIG. 18A and FIG. 18B are schematic cross-sectional views showing the manufacturing method of the semiconductor device according to the seventh embodiment.

FIG. 19A and FIG. 19B are schematic cross-sectional views showing the manufacturing method of the semiconductor device according to the seventh embodiment.

FIG. 20A and FIG. 20B are schematic cross-sectional views showing the manufacturing method of the semiconductor device according to the seventh embodiment.

FIG. 21 is a schematic cross-sectional view showing the manufacturing method of the semiconductor device according to the seventh embodiment.

FIG. 22A and FIG. 22B are schematic cross-sectional views showing the manufacturing method of the semiconductor device according to a modification of the seventh embodiment.

FIG. 23 is a schematic cross-sectional view showing the manufacturing method of the semiconductor device according to a modification of the seventh embodiment.

FIG. 24A and FIG. 24B are schematic cross-sectional views showing the manufacturing method of the semiconductor device according to the eighth embodiment.

FIG. 25A and FIG. 25B are schematic cross-sectional views showing the manufacturing method of the semiconductor device according to the eighth embodiment.

FIG. 26A and FIG. 26B are schematic cross-sectional views showing the manufacturing method of the semiconductor device according to the eighth embodiment.

FIG. 27 is a schematic cross-sectional view of the semiconductor device according to a comparative example.

### DETAILED DESCRIPTION

Below, the embodiments will be described with reference to the drawings, in which in each drawing the same reference numerals are used for the same components.

### First Embodiment

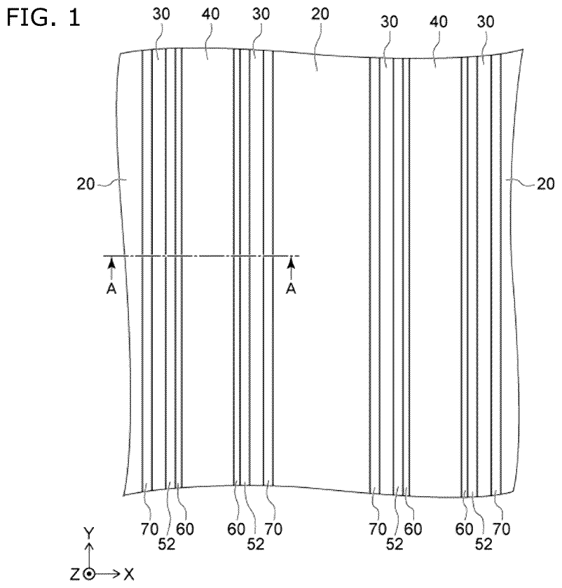

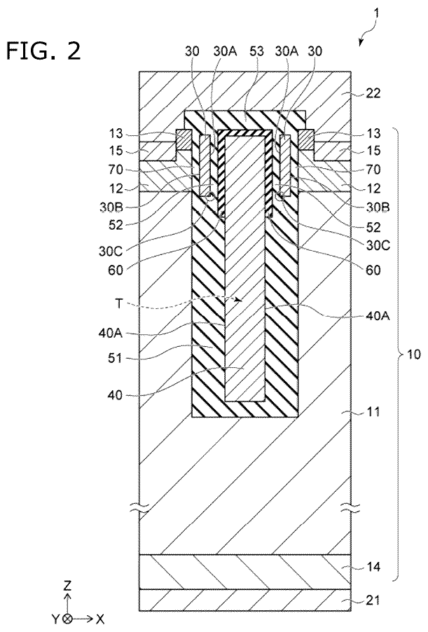

FIG. 1 is a schematic plan view showing the arrangement relationship of the main components in a semiconductor device 1 according to a first embodiment. the cross-section shown in FIG. 2 corresponds to the A-A cross-section in FIG. 1.

In each drawing, the direction along a Z-axis is referred to as a first direction Z, the direction along an X-axis is referred to as a second direction X, and the direction along a Y-axis is referred to as a third direction Y. The first direction Z, the second direction X, and the third direction Y are orthogonal to each other. For example, the arrow direction of the Z-axis is relatively upward.

As shown in FIG. 2, the semiconductor device 1 according to the first embodiment includes a first electrode 21, a second electrode 22, and a semiconductor layer 10. The first electrode 21 and the second electrode 22 are positioned apart in the first direction Z.

The semiconductor layer 10 is positioned between the first electrode 21 and the second electrode 22 in the first direction Z. As a material for the semiconductor layer 10, silicon can be used, for example. Alternatively, materials such as silicon carbide or gallium nitride may be used for the semiconductor layer 10. In this embodiment, a first conductivity type in the semiconductor layer 10 is described as n-type and a second conductivity type as p-type, but the first conductivity type may be p-type and the second conductivity type may be n-type.

The semiconductor layer 10 includes an n-type first semiconductor layer 11, a p-type second semiconductor layer 12 provided on the first semiconductor layer 11, and an n-type third semiconductor layer 13 provided on the second semiconductor layer 12. The n-type impurity concentration of the third semiconductor layer 13 is higher than the n-type impurity concentration of the first semiconductor layer 11. Additionally, the semiconductor layer 10 includes a fourth semiconductor layer 14 provided between the first electrode 21 and the first semiconductor layer 11, and a p-type fifth semiconductor layer 15 provided on the second semiconductor layer 12. The p-type impurity concentration of the fifth semiconductor layer 15 is higher than the p-type impurity concentration of the second semiconductor layer 12.

The semiconductor device 1 has, for example, a vertical MOSFET (Metal-Oxide-Semiconductor Field Effect Transistor) structure. In the MOSFET, the first electrode 21 functions as a drain electrode, the second electrode 22 functions as a source electrode, the first semiconductor layer 11 functions as a drift layer, the second semiconductor layer 12 functions as a base layer, the third semiconductor layer 13 functions as a source layer, and the fourth semiconductor layer 14 functions as an n-type drain layer with a higher n-type impurity concentration than the first semiconductor layer 11.

Alternatively, the semiconductor device 1 may have a vertical IGBT (Insulated Gate Bipolar Transistor) structure. In the IGBT, the first electrode 21 functions as a collector electrode, the second electrode 22 functions as an emitter electrode, the first semiconductor layer 11 functions as a drift layer, the second semiconductor layer 12 functions as a base layer, the third semiconductor layer 13 functions as an emitter layer, and the fourth semiconductor layer 14 functions as a p-type collector layer. In the IGBT, a buffer layer with a higher n-type impurity concentration than the first semiconductor layer 11 may be provided between the fourth semiconductor layer 14 (collector layer) and the first semiconductor layer 11 (drift layer).

The first electrode 21 is in contact with and electrically connected to the fourth semiconductor layer 14.

The second electrode 22 is in contact with and electrically connected to the third semiconductor layer 13. Additionally, the second electrode 22 is in contact with and electrically connected to the fifth semiconductor layer 15.

The semiconductor device 1 further includes a field plate electrode 40 as a third electrode and a gate electrode 30 as a fourth electrode. The gate electrode 30 and the field plate electrode 40 extend in the first direction Z from the upper surface on the side of the second electrode 22 in the semiconductor layer 10. The gate electrode 30 and the field plate electrode 40 are positioned in the same trench T formed in the semiconductor layer 10. For example, in one trench T, two gate electrodes 30 and one field plate electrode 40 are positioned. In one trench T, the field plate electrode 40 is positioned between the two gate electrodes 30 that are spaced apart in the second direction X.

The lower end of the field plate electrode 40 is positioned closer to the first electrode 21 than the lower end of the gate electrode 30. That is, the shortest distance in the first direction Z between the lower end of the field plate electrode 40 and the first electrode 21 is shorter than the shortest distance in the first direction Z between the lower end of the gate electrode 30 and the first electrode 21. The lower end of the gate electrode 30 is positioned below the pn junction between the second semiconductor layer 12 and the first semiconductor layer 11. The lower end of the field plate electrode 40 does not reach the fourth semiconductor layer 14.

The gate electrode 30 includes a first side 30A facing a side 40A of the field plate electrode 40 in the second direction X, and a second side 30B located opposite the first side 30A in the second direction X. One field plate electrode 40 includes two sides 40A located opposite each other in the second direction X.

As shown in FIG. 1, the gate electrode 30 and the field plate electrode 40 extend in the third direction Y. The configuration shown in FIG. 1 is repeated in the second direction X. Multiple gate electrodes 30 and multiple field plate electrodes 40 extending in the third direction Y are arranged in a stripe pattern.

The gate electrode 30 and the field plate electrode 40 are conductive. The gate electrode 30 and the field plate electrode 40 contain silicon. The gate electrode 30 and the field plate electrode 40 are, for example, polycrystalline silicon layers.

The semiconductor device 1 further includes a gate insulating film 70 (shown in FIG. 1 and FIG. 2). The gate insulating film 70 is provided between the second side 30B of the gate electrode 30 and the semiconductor layer 10. The second side 30B of the gate electrode 30 faces the second semiconductor layer 12 via the gate insulating film 70. In this embodiment, the gate insulating film 70 is, for example, a silicon oxide film.

The semiconductor device 1 further includes a first insulating film 51 (FIG. 2). The first insulating film 51 is provided between the side 40A of the field plate electrode 40 and the semiconductor layer 10, and between the lower end of the field plate electrode 40 and the semiconductor layer 10. The first insulating film 51 is, for example, a silicon oxide film.

The semiconductor device 1 further includes a nitride film 60 (FIG. 2). The nitride film 60 is provided on the side 40A of the field plate electrode 40. The nitride film 60 directly contacts the side 40A of the field plate electrode 40. In this embodiment, the nitride film 60 is provided on the side 40A of the field plate electrode 40, facing the first side 30A of the gate electrode 30 in the second direction X. The nitride film 60 extends further downward from the portion facing the first side 30A of the gate electrode 30 in the second direction X. The lower end of the nitride film 60 provided on the side 40A of the field plate electrode 40 is located below the corner 30C between the first side 30A and the bottom surface of the gate electrode 30. Additionally, the nitride film 60 is also provided in contact with the upper surface of the field plate electrode 40. The nitride film 60 is, for example, a silicon nitride film (SiN) or a silicon oxynitride film (SiON).

The semiconductor device 1 further includes a second insulating film 52 (FIG. 1 and FIG. 2). The second insulating film 52 is provided between the first side 30A of the gate electrode 30 and the nitride film 60 provided on the side 40A of the field plate electrode 40. The second insulating film 52 contacts the first side 30A of the gate electrode 30. The second insulating film 52 is, for example, a silicon oxide film.

The semiconductor device 1 further includes a third insulating film 53 (FIG. 2). The third insulating film 53 is provided between the upper surface of the gate electrode 30 and the second electrode 22, and between the field plate electrode 40 and the second electrode 22. The third insulating film 53 is, for example, a silicon oxide film.

When the first electrode 21 is applied with a first potential (e.g., a positive potential), the second electrode 22 is applied with a second potential lower than the first potential (e.g., a ground potential), and a gate voltage equal to or greater than the threshold is applied to the gate electrode 30, an n-type channel is formed in the region of the second semiconductor layer 12 facing the second side 30B of the gate electrode 30. Through the fourth semiconductor layer 14, the first semiconductor layer 11, the channel, and the third semiconductor layer 13, current flows between the first electrode 21 and the second electrode 22, and the semiconductor device 1 is turned on.

In the OFF state of the semiconductor device 1, in which the application of a voltage equal to or greater than the threshold to the gate electrode 30 is stopped, a depletion layer spreads from the pn junction between the second semiconductor layer 12 and the first semiconductor layer 11, and from the boundary between the first insulating film 51 and the first semiconductor layer 11, maintaining the breakdown voltage of the semiconductor device 1.

The field plate electrode 40 is electrically connected to the second electrode 22. In the OFF state, the field plate electrode 40 moderates the electric field distribution of the first semiconductor layer 11 (drift layer) and improves the breakdown voltage of the semiconductor device 1.

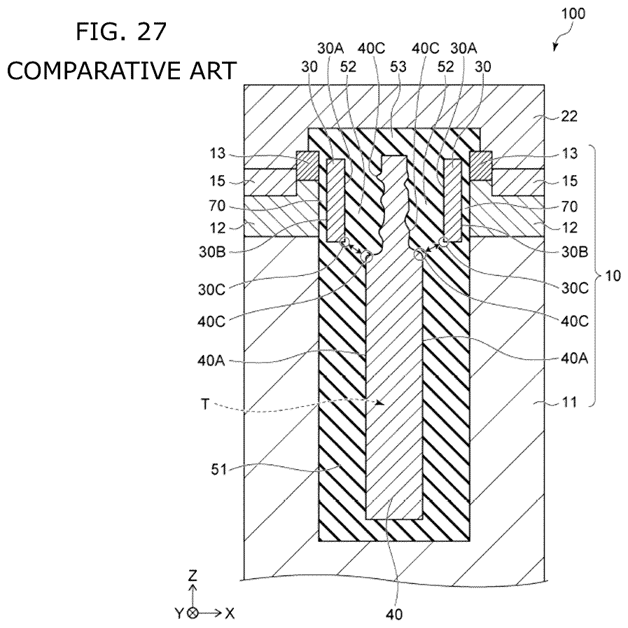

Referring to FIG. 27, a semiconductor device 100 according to a comparative example will be described.

The configuration of the comparative example of FIG. 27 in which the field plate electrode 40 and the gate electrode 30 are provided in the same trench T can be formed as described below.

After forming the trench T in the semiconductor layer 10, the field plate electrode 40 is embedded in the trench T via the first insulating film 51. After forming the field plate electrode 40, the upper part of the first insulating film 51 is removed. By removing the upper part of the first insulating film 51, the sidewalls of the upper region of the trench T formed are thermally oxidized to form the second insulating film 52 and the gate insulating film 70. After this, the gate electrode 30 is embedded in the upper region of the trench T.

In the process of thermally oxidizing the sidewalls of the upper region of the trench T, the exposed upper part of the side surface 40A of the field plate electrode 40, which is a silicon layer, is acceleratedly thermally oxidized, and the width of the upper part of the field plate electrode 40 (the width in the second direction X) becomes smaller. As shown in FIG. 27, a convex portion is formed on the upper part of the field plate electrode 40. Protrusions 40C are easily formed on the surface of the convex portion formed by this accelerated thermal oxidation. Electric fields tend to concentrate on a corner 30C of the gate electrode 30 and the protrusion 40C of the field plate electrode 40. When there is the protrusion 40C near the corner 30C of the gate electrode 30, the electric field strength between the corner 30C of the gate electrode 30 and the protrusion 40C of the field plate electrode 40 increases, and the insulating film between the corner 30C and the protrusion 40C undergoes dielectric breakdown. As a result, leakage current is likely to occur between the gate electrode 30 and the field plate electrode 40.

According to this first embodiment of FIG. 1 and FIG. 2, in contrast to the comparative example of FIG. 27, by forming the nitride film 60 on the upper part of a side surface 40A of the field plate electrode 40, the upper part of the side surface 40A of the field plate electrode 40 can be protected from thermal oxidation. As a result, no protrusions are formed on the side surface 40A of the field plate electrode 40 facing the corner 30C of the gate electrode 30, and the dielectric breakdown voltage between the gate electrode 30 and the field plate electrode 40 can be increased. Consequently, the leakage current between the gate electrode 30 and the field plate electrode 40 can be reduced.

The nitride film 60 is located at least on the side surface 40A of the field plate electrode 40 facing the corner 30C between a first side surface 30A and the bottom surface of the gate electrode 30. The nitride film 60 itself functions as an insulating film that enhances the dielectric breakdown electric field strength between the corner 30C of the gate electrode 30 and the side surface 40A of the field plate electrode 40. In particular, it is preferable to use a silicon oxynitride film as the nitride film 60. Such asilicon oxynitride film has a higher dielectric breakdown electric field strength than a silicon oxide film and a silicon nitride film.

In the semiconductor device 100 according to the comparative example of FIG. 27, the thermal oxide film expands in volume in the lateral direction (second direction X) at the upper part of the field plate electrode 40, increasing the surface stress of the wafer and making the wafer prone to warping. In contrast, according to the present embodiment of FIG. 1 and FIG. 2, the lateral volume expansion of the oxide film at the upper part of the field plate electrode 40 can be suppressed, thereby reducing the warping of the wafer.

Next, other embodiments will be described. The other embodiments mainly describe configurations different from the first embodiment of FIG. 1 and FIG. 2.

### Second Embodiment

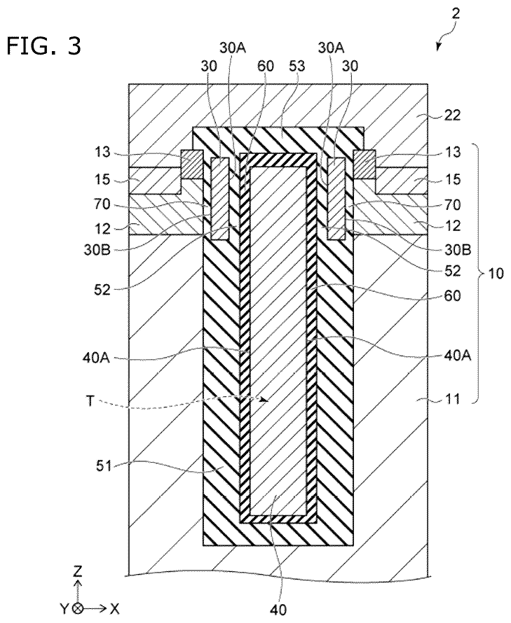

According to a semiconductor device 2 of a second embodiment shown in FIG. 3, the nitride film 60 is provided in contact with the entire surface of the side surface 40A of the field plate electrode 40. This reduces the leakage current between the gate electrode 30 and the field plate electrode 40. In this case, it is also preferable to use a silicon oxynitride film as the nitride film 60.

According to the second embodiment, the nitride film 60 is also provided in contact with the upper and lower surfaces of the field plate electrode 40.

### Third Embodiment

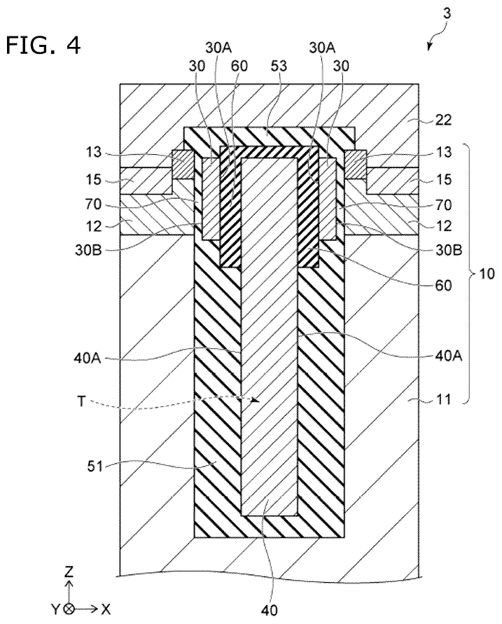

According to a semiconductor device 3 of a third embodiment shown in FIG. 4, the silicon oxynitride film as the nitride film 60 is provided in all areas between the first side surface 30A of the gate electrode 30 and the side surface 40A of the field plate electrode 40. The silicon oxynitride film as the nitride film 60 is in contact with the first side surface 30A of the gate electrode 30 and the side surface 40A of the field plate electrode 40. There is no silicon oxide film or silicon nitride film provided between the first side surface 30A of the gate electrode 30 and the side surface 40A of the field plate electrode 40. This reduces the leakage current between the gate electrode 30 and the field plate electrode 40 compared to when a silicon oxide film is interposed between the first side surface 30A of the gate electrode 30 and the side surface 40A of the field plate electrode 40.

The silicon oxynitride film as the nitride film 60 extends further downward in the second direction X from the portion facing the first side surface 30A of the gate electrode 30. The nitride film 60 is also provided in contact with the upper surface of the field plate electrode 40.

### Fourth Embodiment

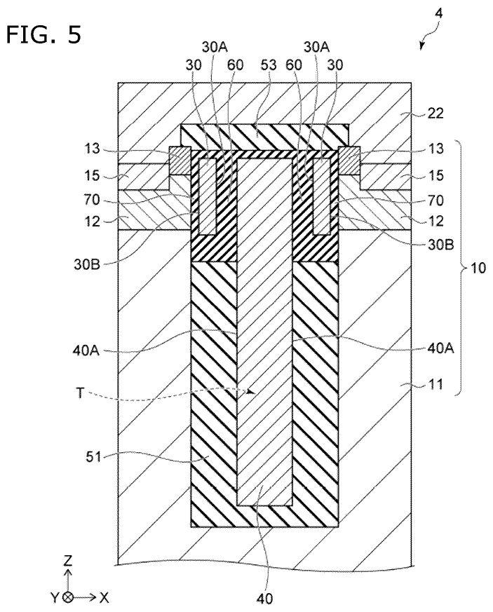

According to a semiconductor device 4 of a fourth embodiment shown in FIG. 5, similar to the third embodiment of FIG. 4, the silicon oxynitride film as the nitride film 60 is provided in all areas between the first side surface 30A of the gate electrode 30 and the side surface 40A of the field plate electrode 40. The nitride film 60 is also provided in contact with the upper surface of the field plate electrode 40.

Furthermore, according to the fourth embodiment of FIG. 5, the gate insulating film 70 is a silicon oxynitride film. Such a silicon oxynitride film is less likely to break atomic bonds compared to a silicon oxide film and a silicon nitride film when an electric field is applied for a long time, making it less prone to damage during the operation of the semiconductor device. Therefore, by using a silicon oxynitride film as the gate insulating film 70, the interface level between the channel and the gate insulating film 70 can be stabilized, threshold fluctuation can be suppressed, and reliability can be improved.

### Fifth Embodiment

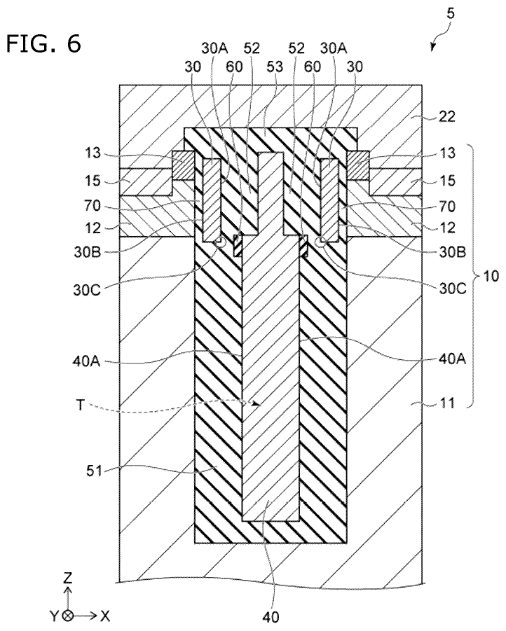

As shown in a semiconductor device 5 of a fifth embodiment in FIG. 6, even if the upper part of the field plate electrode 40 becomes convex due to thermal oxidation, the leakage current between the corner 30C of the gate electrode 30 and the field plate electrode 40 can be reduced by providing the nitride film 60 only in the portion facing the corner 30C between the first side surface 30A and the bottom surface of the gate electrode 30 on the side surface 40A of the field plate electrode 40. In this case, the breakdown voltage can be improved while suppressing the increase in capacitance between the gate electrode 30 and the field plate electrode 40.

### Sixth Embodiment

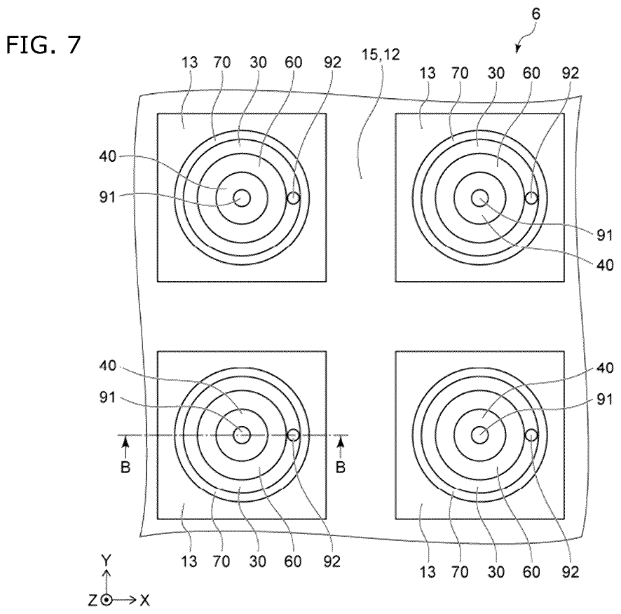

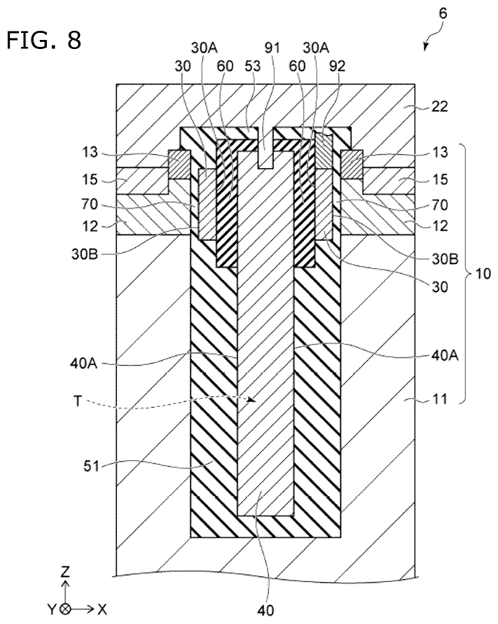

FIG. 7 is a schematic plan view showing the arrangement relationship of the main components in a semiconductor device 6 according to a sixth embodiment. The cross-section shown in FIG. 8 corresponds to the B-B cross-section in FIG. 7.

According to the sixth embodiment, multiple columnar field plate electrodes 40 are arranged in the semiconductor layer 10. The gate electrode 30 surrounds the side surface 40A of the field plate electrode 40. Between the first side surface 30A of the gate electrode 30, which is the inner peripheral surface, and the side surface 40A of the field plate electrode 40, the nitride film 60 is provided in contact with the first side surface 30A and the side surface 40A of the field plate electrode 40. The semiconductor layer 10 surrounds the inner peripheral surface of the gate electrode 30, which is the second side surface 30B, via the gate insulating film 70.

The field plate electrode 40 is electrically connected to the second electrode 22 via the field contact portion 91 provided between the upper part of the field plate electrode 40 and the second electrode 22. The gate electrode 30 is electrically connected to a gate wiring (not shown) via the gate contact portion 92 connected to the upper part of the gate electrode 30.

### Seventh Embodiment

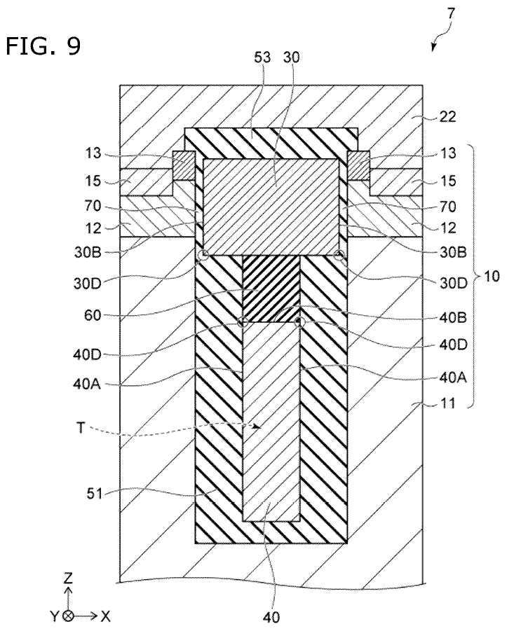

According to a semiconductor device 7 of a seventh embodiment shown in FIG. 9, the gate electrode 30 is provided above the field plate electrode 40 in the semiconductor layer 10 and extends in the third direction Y. One field plate electrode 40 and one gate electrode 30 are arranged in one trench T. The second side surface 30B of the gate electrode 30 faces the second semiconductor layer 12 via the gate insulating film 70. The width of the gate electrode 30 in the second direction X is larger than the width of the field plate electrode 40 in the second direction X.

In addition, the nitride film 60 is provided in contact with the upper surface 40B of the field plate electrode 40. According to the seventh embodiment, the nitride film 60 is in contact with the bottom surface of the gate electrode 30. The nitride film 60 is provided in all areas between the bottom surface of the gate electrode 30 and the upper surface 40B of the field plate electrode 40.

According to this embodiment, by providing the nitride film 60 in contact with the upper surface 40B of the field plate electrode 40 as shown in FIG. 9, it is possible to prevent the formation of a convex portion with a small width due to thermal oxidation at the upper part of the field plate electrode 40. As a result, compared to the comparative example shown in FIG. 27, the distance between the corner 30D of the gate electrode 30 (the corner between the second side surface 30B and the bottom surface of the gate electrode 30) and the corner 40D of the field plate electrode 40 (the corner between the side surface 40A and the upper surface of the field plate electrode 40) can be increased. Consequently, the leakage current between the gate electrode 30 and the field plate electrode 40 can be reduced.

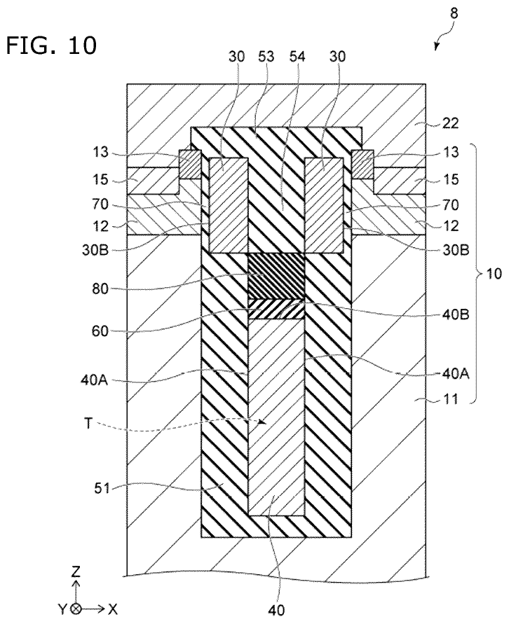

In addition, as shown in FIG. 10 as a modification, the gate electrode 30 may be separated in the second direction X within one trench T.

### Eighth Embodiment

According to a semiconductor device 8 of an eighth embodiment shown in FIG. 10, it further includes a silicate glass film 80 provided on the nitride film 60. The silicate glass film 80 is, for example, a BPSG (boro-phospho silicate glass) film containing boron and phosphorus.

In the further eighth embodiment of FIG. 10, a fourth insulating film 54 is provided between the two gate electrodes 30 above the silicate glass film 80. The fourth insulating film 54 is, for example, a silicon oxide film.

In the configuration shown in FIG. 10, the silicate glass film 80 may be provided between the bottom surface of the gate electrode 30 and the nitride film 60.

The embodiments described above can be appropriately combined within a range that does not cause technical contradictions.

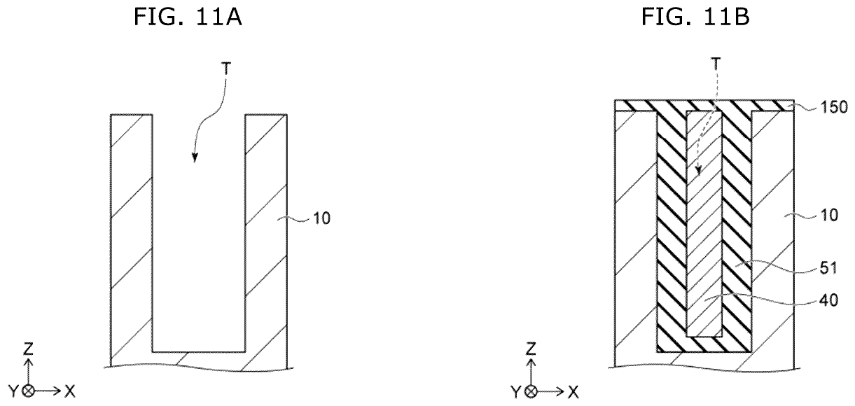

Next, the manufacturing method of the semiconductor device 1 according to the first embodiment will be described with reference to FIGS. 11A to 14B As shown in FIG. 11A, the trench T is formed in the semiconductor layer 10. For example, the trench T can be formed by the RIE (Reactive Ion Etching) method using a mask.

After forming the trench T, as shown in FIG. 11B, the field plate electrode 40 is formed in the trench T via the first insulating film 51. As the first insulating film 51, for example, a silicon oxide film is formed by the CVD (Chemical Vapor Deposition) method or thermal oxidation method. After forming the first insulating film 51, a polycrystalline silicon layer is formed as the field plate electrode 40 inside the first insulating film 51 in the trench T, for example, by the CVD method. After forming the field plate electrode 40 in the trench T, a silicon oxide film 150 is formed on the upper surface of the semiconductor layer 10, the upper surface of the field plate electrode 40, and the upper surface of the first insulating film 51.

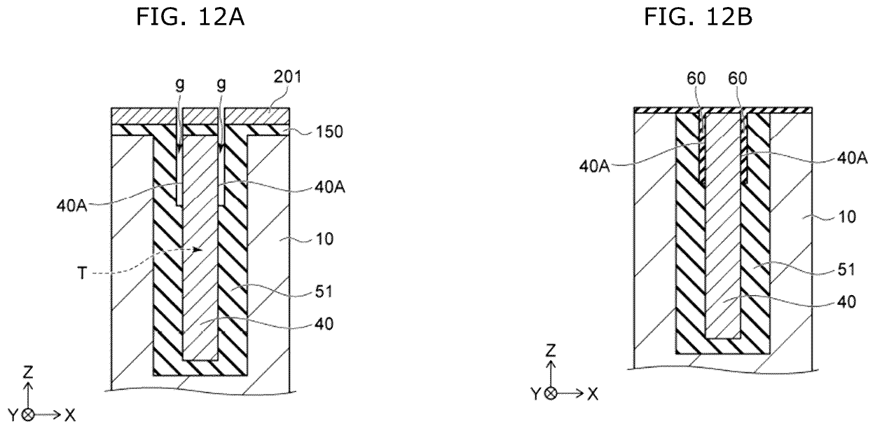

After forming the silicon oxide film 150, as shown in FIG. 12A, a resist 201 is formed on the silicon oxide film 150. Then, using the resist 201 as a mask, the portion adjacent to the upper side surface 40A of the field plate electrode 40 in the first insulating film 51 is removed by the RIE method, and a gap g is formed in the region adjacent to the upper side surface 40A of the field plate electrode 40.

After forming the gap g, the resist 201 and the silicon oxide film 150 are removed. Then, as shown in FIG. 12B, the nitride film 60 is formed in the gap g. The nitride film 60 is in contact with the upper side surface 40A of the field plate electrode 40. The nitride film 60 is also formed on the upper surface of the semiconductor layer 10, the upper surface of the field plate electrode 40, and the upper surface of the first insulating film 51. The nitride film 60 can be formed, for example, by the CVD method.

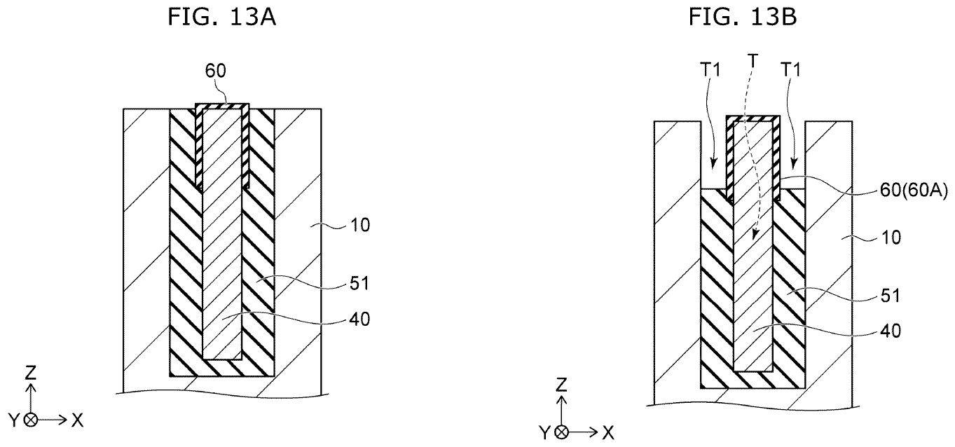

After forming the nitride film 60, the nitride film 60 on the upper surface of the semiconductor layer 10 and the upper surface of the first insulating film 51 is removed. As a result, as shown in FIG. 13A, the upper surface of the semiconductor layer 10 and the upper surface of the first insulating film 51 are exposed. The nitride film 60 on the upper surface of the field plate electrode 40 remains. For example, the nitride film 60 on the upper surface of the semiconductor layer 10 and the upper surface of the first insulating film 51 can be removed by the CDE (Chemical or Conformal Dry Etching) method using a resist formed on the upper surface of the field plate electrode 40 as a mask.

Through the above process, the nitride film 60 (first nitride film 60A) is formed on at least the upper side surface 40A of the field plate electrode 40.

After forming the nitride film 60, the upper part of the first insulating film 51 is removed, and as shown in FIG. 13B, an upper region T1, which is a gap, is formed in the trench T. For example, the upper part of the first insulating film 51 can be removed by the RIE method or the CDE method. In the upper region T1, the nitride film 60 provided on the side surface 40A of the field plate electrode 40 is exposed.

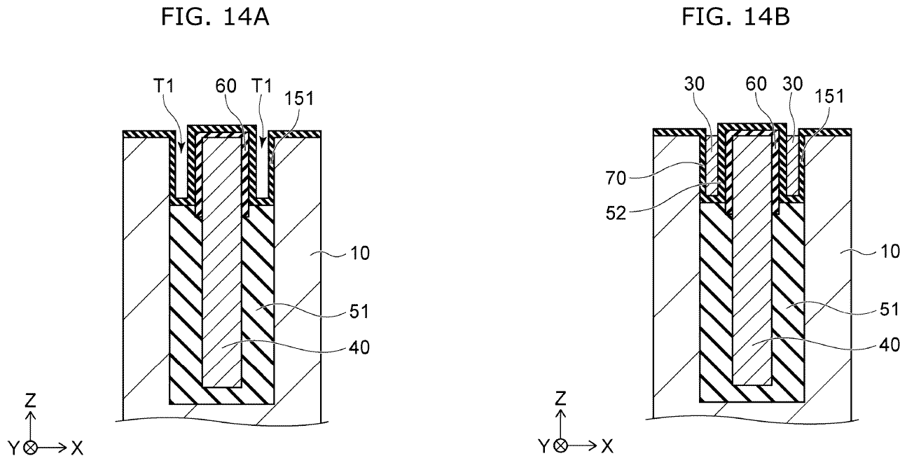

After forming the upper region T1, as shown in FIG. 14A, a silicon oxide film 151 is formed on the sidewalls of the upper region T1 and the upper surface of the first insulating film 51. For example, the silicon oxide film 151 can be formed by the thermal oxidation method or the CVD method. In the process of forming the silicon oxide film 151 in the upper region T1 of the trench T, the nitride film 60 is provided on the upper side surface 40A of the field plate electrode 40. Therefore, the upper part of the field plate electrode 40 is not acceleratedly thermally oxidized, and no protrusions are formed on the upper side surface 40A of the field plate electrode 40 as in the comparative example shown in FIG. 27.

After forming the silicon oxide film 151, as shown in FIG. 14B, the gate electrode 30 is formed in the upper region T1 adjacent to the nitride film 60 in the trench T. The gate electrode 30 can be formed, for example, by the CVD method to form a polycrystalline silicon layer. The silicon oxide film 151 located between the gate electrode 30 and the nitride film 60 becomes the aforementioned second insulating film 52. The silicon oxide film 151 located between the gate electrode 30 and the semiconductor layer 10 becomes the aforementioned gate insulating film 70.

After forming the gate electrode 30, for example, by the ion implantation method, the second semiconductor layer 12, the third semiconductor layer 13, and the fifth semiconductor layer 15 are formed in the semiconductor layer 10. Furthermore, the process of forming the third insulating film 53 and the process of forming the second electrode 22 follow.

Before forming the gate electrode 30, in the process of forming the silicon oxide film 151 on the sidewalls of the upper region T1 of the trench T, a second nitride film may be formed instead of the silicon oxide film 151. This results in the semiconductor device 4 according to the fourth embodiment shown in FIG. 5.

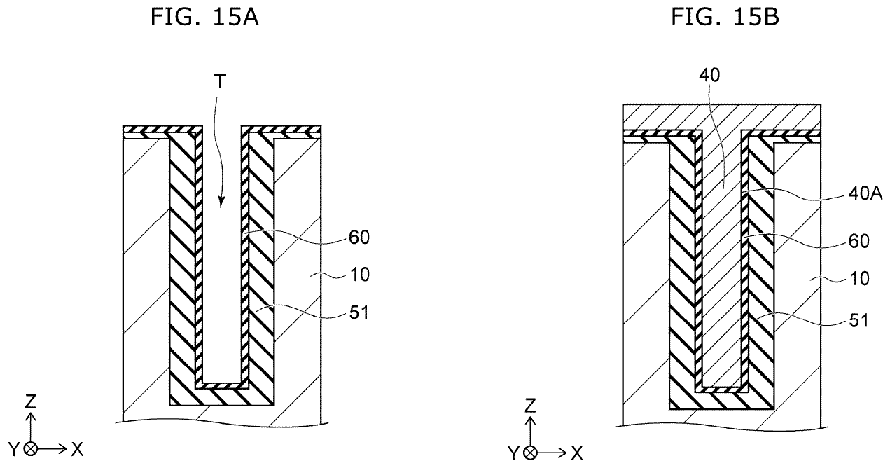

Next, the manufacturing method of the semiconductor device 2 according to the second embodiment will be described with reference to FIGS. 15A to 17B.

As shown in FIG. 15A, a trench T is formed in the semiconductor layer 10, and the first insulating film 51 is formed in the trench T. After this, the nitride film 60 is formed inside the first insulating film 51 in the trench T. The nitride film 60 is also deposited above the upper surface of the semiconductor layer 10 and above the trench T.

After forming the nitride film 60, as shown in FIG. 15B, the field plate electrode 40 is formed inside the nitride film 60 in the trench T. The field plate electrode 40 is embedded in the trench T and is also deposited above the upper surface of the semiconductor layer 10 and above the nitride film 60 in the trench T.

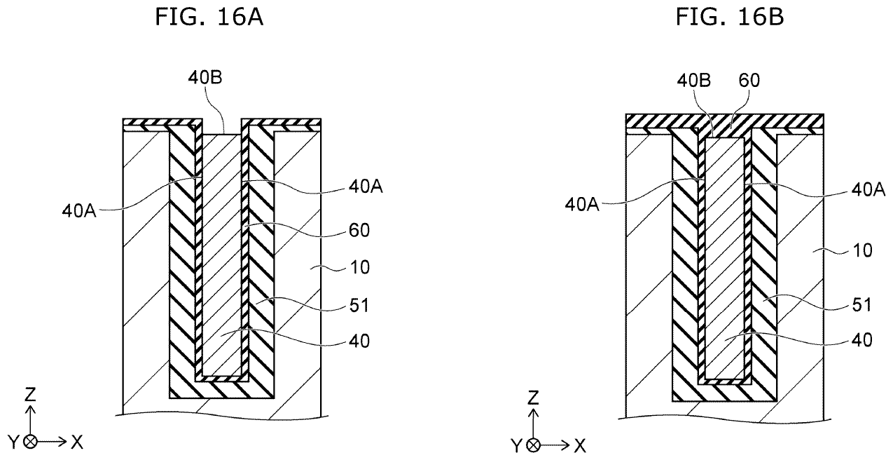

After forming the field plate electrode 40, the field plate electrode 40 deposited above the upper surface of the semiconductor layer 10 and above the trench T is removed, for example, by etching. As a result, as shown in FIG. 16A, the nitride film 60 located above the upper surface of the semiconductor layer 10 and above the trench T is exposed. The upper surface 40B of the field plate electrode 40 in the trench T is also exposed.

As shown in FIG. 16B, the nitride film 60 is further formed on the nitride film 60 located above the upper surface of the semiconductor layer 10 and above the trench T, and on the upper surface 40B of the field plate electrode 40.

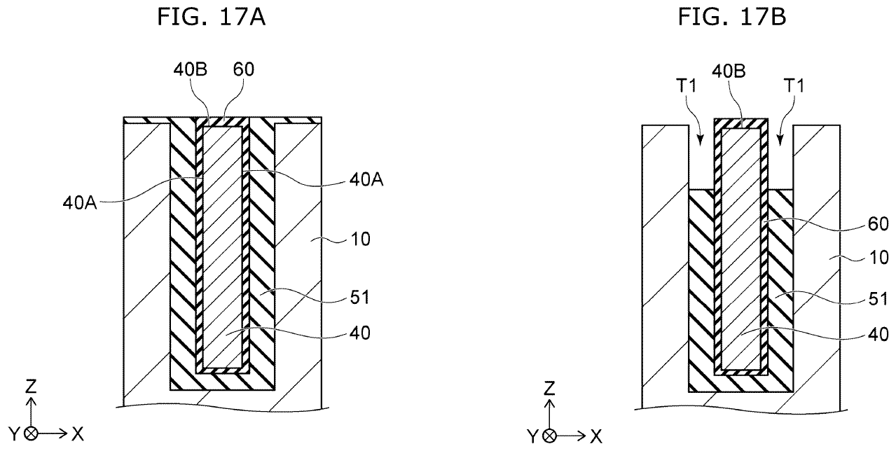

The nitride film 60 on the upper surface of the semiconductor layer 10 and the upper surface of the first insulating film 51 is removed, for example, by etching. As shown in FIG. 17A, the nitride film 60 on the upper surface 40B of the field plate electrode 40 remains. This results in a structure in which the side surface 40A, the upper surface 40B, and the lower surface of the field plate electrode 40 are covered with the nitride film 60.

After this, the upper part of the first insulating film 51 is removed, and as shown in FIG. 17B, the upper region T1 is formed in the trench T. The subsequent processes are the same as those in the first embodiment.

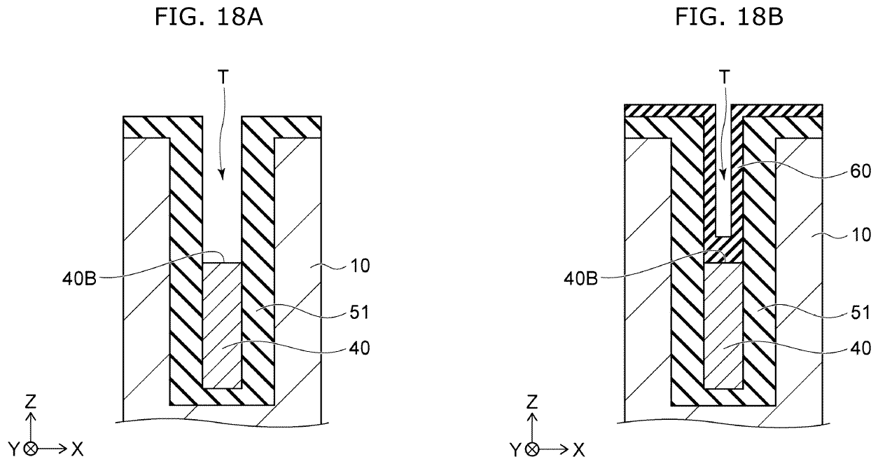

Next, the manufacturing method of the semiconductor device 7 according to the seventh embodiment will be described with reference to FIGS. 18A to 21.

As shown in FIG. 18A, after embedding the field plate electrode 40 in the trench T formed in the semiconductor layer 10 via the first insulating film 51, the upper part of the field plate electrode 40 is removed by etching.

As shown in FIG. 18B), the nitride film 60 is formed in the region above the field plate electrode 40 in the trench T. The nitride film 60 is formed on the upper surface 40B of the field plate electrode 40, the sidewalls, and the upper surface of the first insulating film 51.

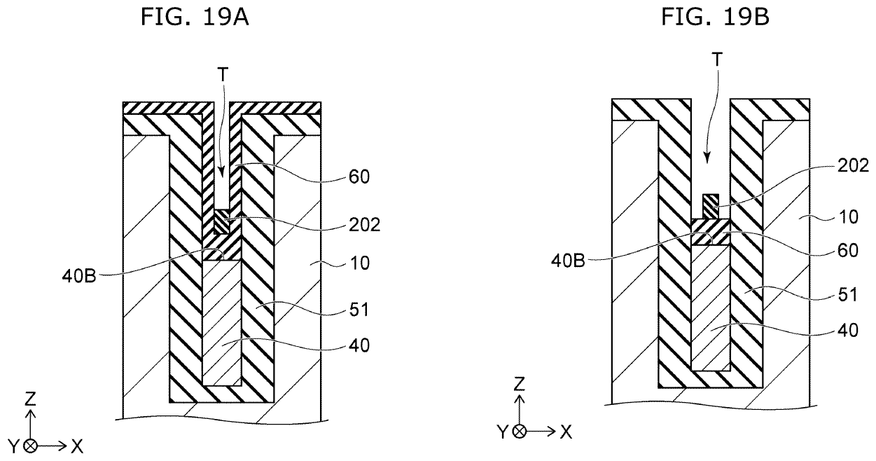

As shown in FIG. 19A, a mask 202 is formed on the nitride film 60 provided on the upper surface 40B of the field plate electrode 40 in the trench T. The mask 202 can be formed, for example, by embedding a silicon oxide film inside the nitride film 60 in the trench T and then recessing the silicon oxide film by etching.

The nitride film 60 is etched using the silicon oxide film mask 202. As a result, as shown in FIG. 19B, the nitride film 60 formed on the upper surface and sidewalls of the first insulating film 51 is removed, and the nitride film 60 on the upper surface 40B of the field plate electrode 40 remains.

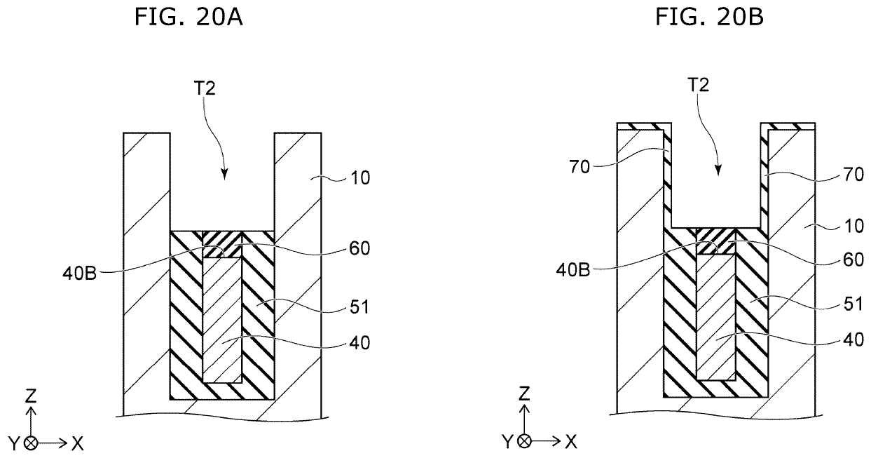

After this, the first insulating film 51 on the semiconductor layer 10 and the first insulating film 51 formed on the upper sidewalls of the trench T are removed by etching. At this time, the mask 202 is also removed. As a result, as shown in FIG. 20A, the upper region T2, which is a space for arranging the gate electrode above the nitride film 60 and above the first insulating film 51 in the trench T, is formed.

As shown in FIG. 20B, the gate insulating film 70 is formed on the side surface of the semiconductor layer 10 exposed in the upper region T2. For example, the gate insulating film 70 is formed by the thermal oxidation method. At this time, since the nitride film 60 is provided on the upper surface of the field plate electrode 40, the upper part of the field plate electrode 40 is not oxidized and does not become convex.

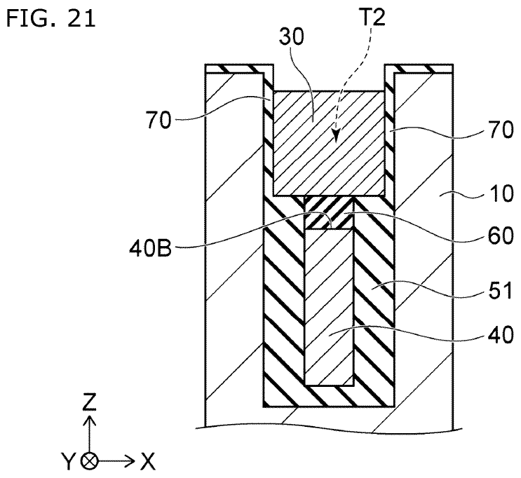

After forming the gate insulating film 70, as shown in FIG. 21, the gate electrode 30 is formed in the upper region T2.

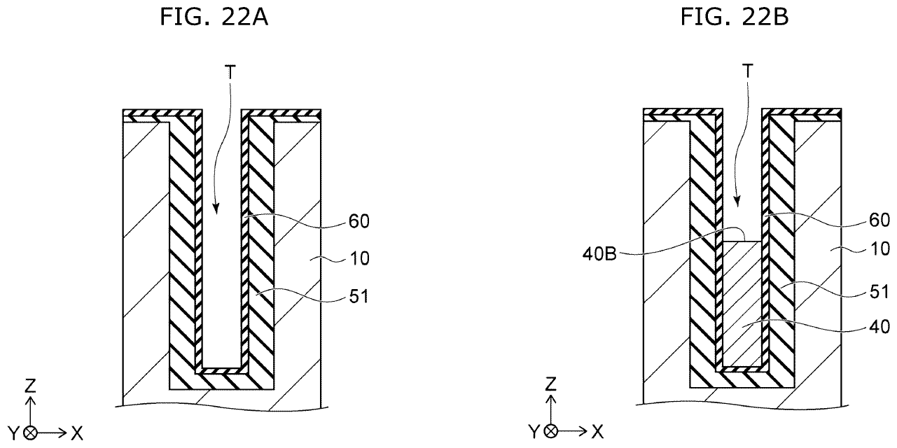

As shown in FIG. 22A, after forming the first insulating film 51 in the trench T, the nitride film 60 may be formed on the bottom and sidewalls of the first insulating film 51 in the trench T before forming the field plate electrode 40.

After this, as shown in FIG. 22B, the field plate electrode 40 is embedded inside the nitride film 60 in the trench T, and the upper part of the field plate electrode 40 is recessed.

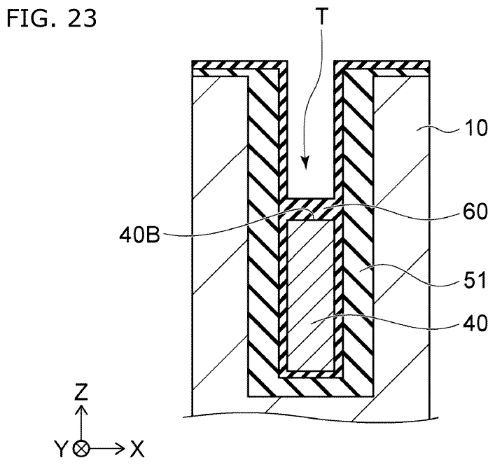

As shown in FIG. 23, an additional nitride film 60 is formed on the upper surface 40B of the field plate electrode 40. The subsequent processes are the same as those shown in FIGS. 19A to 21.

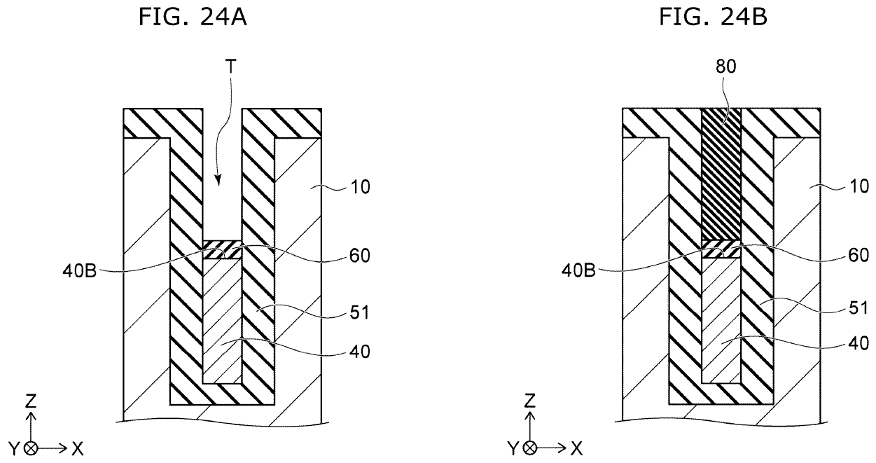

Next, the manufacturing method of the semiconductor device 8 according to the eighth embodiment will be described with reference to FIGS. 24A to 26B.

After the process shown in FIG. 19B, the mask 202 is removed. This state is shown in FIG. 24A.

As shown in FIG. 24B, the silicate glass film 80 is embedded in the region above the nitride film 60 in the trench T.

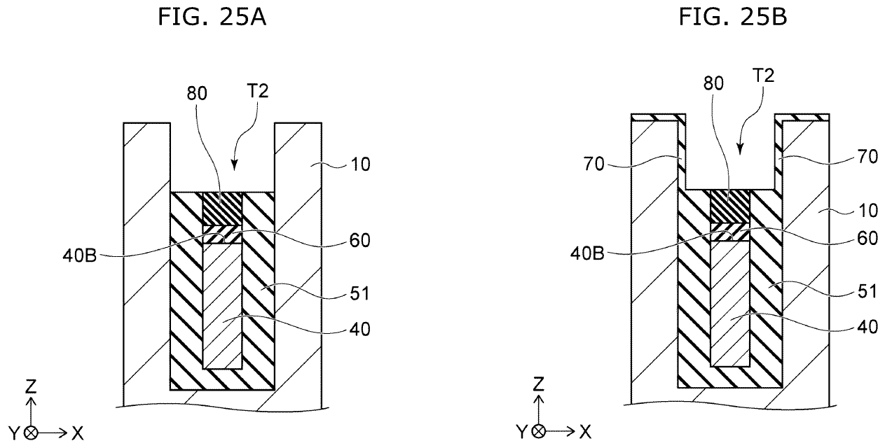

The upper part of the silicate glass film 80 and the upper part of the first insulating film 51 are removed by etching, and as shown in FIG. 25A, the upper region T2, which is a space for arranging the gate electrode above the silicate glass film 80 and above the first insulating film 51 in the trench T, is formed.

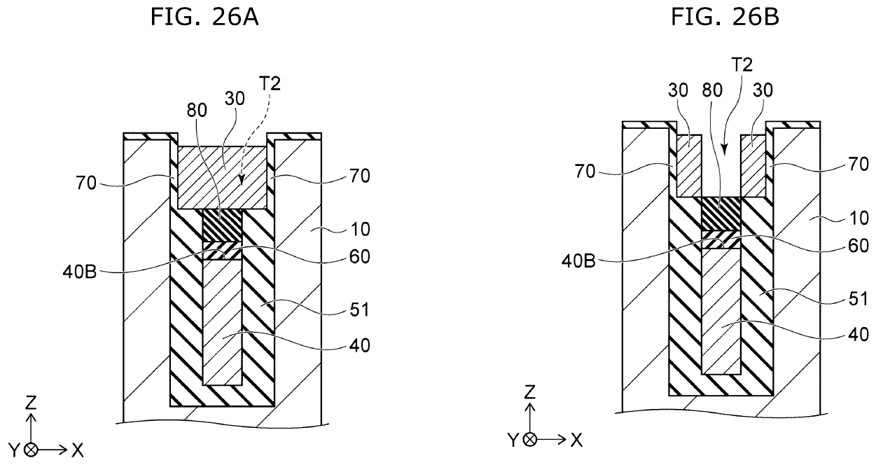

As shown in FIG. 25B, the gate insulating film 70 is formed on the side surface of the semiconductor layer 10 exposed in the upper region T2. After forming the gate insulating film 70, as shown in FIG. 26A, the gate electrode 30 is formed in the upper region T2.

After this, the gate electrode 30 on the silicate glass film 80 may be removed by the RIE method, for example, and as shown in FIG. 26B, the gate electrode 30 may be separated in the second direction X.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device comprising:
a first electrode;
a second electrode;
a semiconductor layer provided between the first electrode and the second electrode in a first direction;
a third electrode extending in the first direction within the semiconductor layer and containing silicon;
a fourth electrode extending in the first direction within the semiconductor layer, including a first side surface facing a side surface of the third electrode in a second direction orthogonal to the first direction, and a second side surface located on an opposite side of the first side surface in the second direction;
an insulating film provided between the second side surface of the fourth electrode and the semiconductor layer; and
a nitride film in contact with the side surface of the third electrode; wherein
the nitride film is located between the third electrode and at least a portion of a corner of the fourth electrode between the first side surface and a bottom surface of the fourth electrode.

2. The semiconductor device according to claim 1, wherein the nitride film is a silicon nitride film or a silicon oxynitride film.

3. The semiconductor device according to claim 1, wherein the nitride film is provided in all areas between the first side surface of the fourth electrode and the side surface of the third electrode.

4. The semiconductor device according to claim 1, wherein
the nitride film is provided on an entirety of the side surface of the third electrode.

5. The semiconductor device of claim 3, wherein the nitride film is further provided to surround the fourth electrode.

6. The semiconductor device of claim 1, wherein each of the third electrode, the fourth electrode, the insulating film, and the nitride film are formed in a columnar shape.

7. The semiconductor device according to claim 1, wherein the insulating film is a silicon oxynitride film.

8. A semiconductor device comprising:
a first electrode;
a second electrode;
a semiconductor layer provided between the first electrode and the second electrode in a first direction;
a third electrode extending in the first direction within the semiconductor layer and containing silicon;
a fourth electrode provided above the third electrode in the semiconductor layer; and
a nitride film provided in contact with an upper surface of the third electrode.

9. The semiconductor device according to claim 8, further comprising a silicate glass film provided on the nitride film.

10. The semiconductor device according to claim 9, wherein the silicate glass film contains boron and phosphorus.

11. The semiconductor device according to claim 8, wherein the third electrode is connected to the second electrode.

12. The semiconductor device according to claim 8, wherein the nitride film is further provided in contact with a lower surface of the fourth electrode.

13. The semiconductor film according to claim 9, wherein the fourth electode is divided into plural fourth electrode portions.

14. The semiconductor device according to claim 13, wherein the silicate glass film is further provided in-between the plural fourth electrode portions.

15. A method of manufacturing a semiconductor device comprising:
forming a trench in a semiconductor layer;
forming an electrode containing silicon in the trench via a first insulating film;
forming a first nitride film on at least an upper side surface of the electrode; and
forming a gate electrode in an upper region adjacent to the first nitride film in the trench.

16. The method of manufacturing a semiconductor device according to claim 15, further comprising forming a second nitride film on sidewalls of the upper region in the trench before forming the gate electrode.
